(19) United States
(12) Patent Application Publication
(10) Pub. No.: US 2010/0237401 A1
(43) Pub. Date: Sep. 23, 2010

(54) GATE STRUCTURES OF SEMICONDUCTOR DEVICES

(75) Inventors: JEONG-DONG CHOE, Anyang-si (KR); Kyoung-Sub Shin, Seongnam-si (KR); Kyoung-Hwan Yeo, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/726,836

(22) Filed: Mar. 18, 2010

(30) Foreign Application Priority Data
Mar. 18, 2009 (KR) 10-2009-0023263

(51) Int. Cl. H01L 29/792

(52) U.S. Cl. 257/324; 257/E29.309

(57) ABSTRACT

Gate structures of semiconductor devices and methods of forming gate structures of semiconductor devices are provided. A first insulating pattern may be disposed on an active region of a semiconductor substrate. A data storage pattern may be disposed on the first insulating pattern. A second insulating pattern may be disposed on the data storage pattern and may contact the data storage pattern. A first conductive pattern may conform to the second insulating pattern and to sidewalls of a mold comprising the second insulating pattern. A second conductive pattern may be disposed within a cavity defined by the first conductive pattern. Spacers may be formed on sidewalls of at least one of the first insulating pattern, the data storage pattern, the second insulating pattern, and the conductive pattern.

### CROSS-REFERENCE TO RELATED APPLICATION

This application claims priority under 35 U.S.C. §119 to Korean Patent Application No. 10-2009-0023263, filed on Mar. 18, 2009, the contents of which are incorporated herein by reference in their entirety.

### BACKGROUND

1. Field

The field relates generally to semiconductor devices and semiconductor device fabrication and, more particularly, to semiconductor device gate structures and methods of forming semiconductor device gate structures.

2. Description of Related Art

Recently, non-volatile memory cells have been fabricated by applying an oxide layer, a nitride layer, and a metal layer, which are stacked, to a gate structure in a semiconductor device. Accordingly, the non-volatile memory cell may contribute to high integration and/or high speed of the semiconductor device through the gate structure.

However, the non-volatile memory cell may contaminate the oxide layer and the nitride layer with metal during the formation of the gate structure. In addition, because the metal layer is continuously etched until the nitride layer and the oxide layer are completely etched, the gate structure may not have a desired patterning profile on the metal layer.

### SUMMARY

Various embodiments provide a gate structure having a patterning profile on a metal layer of a non-volatile memory cell in a semiconductor device.

Some embodiments also provide methods of forming gate structures which can prevent metal contamination from a metal layer during formation of a non-volatile memory cell in a semiconductor device.

Some embodiments also provide semiconductor devices having a gate structure that may be formed by molding a metal layer on a mold, and methods of fabricating the semiconductor devices.

Various embodiments are directed to a gate structure in semiconductor devices including an active region of a semiconductor substrate. A first insulating pattern may be disposed on the active region. A data storage pattern may be disposed on the first insulating pattern. A second insulating pattern may be disposed on the data storage pattern. A first conductive pattern may conform to the second insulating pattern and to sidewalls of a mold comprising the second insulating pattern. A second conductive pattern may be disposed within a cavity defined by the first conductive pattern.

According to some embodiments, the first conductive pattern may surround a bottom surface and sidewalls of the second conductive pattern and expose a top surface of the second conductive pattern, and a protective pattern may be disposed on the top surface of the second conductive pattern.

According to some embodiments, the second insulating pattern may include lower and upper insulating patterns that are stacked. The lower and upper insulating patterns may have different dielectric constants from each other.

According to some embodiments, sidewalls of the first conductive pattern may have substantially the same surface alignment as sidewalls of the first insulating pattern, the data storage pattern, the second insulating pattern, and the protective pattern.

According to some embodiments, the mold may further include sidewall spacers disposed on sidewalls of the first insulating pattern, the data storage pattern, the second insulating pattern, the first conductive pattern, and the protective pattern.

According to some embodiments, sidewalls of the first insulating pattern may have substantially the same surface alignment as the sidewalls of the data storage pattern and the second insulating pattern. The sidewalls of the first conductive pattern and the protective pattern may have a different surface alignment from the sidewalls of the first insulating pattern, the data storage pattern, and the second insulating pattern.

According to some embodiments, the mold may further include sidewall spacers disposed on sidewalls of the first conductive pattern and the protective pattern. The sidewalls of the first insulating pattern, the data storage pattern, and the second insulating pattern may be aligned with sidewalls of lower portions of the spacers.

According to some embodiments, a bottom surface and sidewalls of the first conductive pattern may be surrounded by the second insulating pattern, and the protective pattern may be in contact with the first conductive pattern, the second conductive pattern, and the second insulating pattern.

According to some embodiments, the first conductive pattern and the second conductive pattern may comprise a control gate of a non-volatile memory cell. The data storage pattern may set the non-volatile memory cell to a program state or an erase state by receiving the influence of an electric field generated by the first conductive pattern and the second conductive pattern.

According to some embodiments, the protective pattern may have the same width as the first insulating pattern and the data storage pattern, and may have a different width from the first conductive pattern.

Some embodiments are directed to methods of forming a gate structure of semiconductor devices, including forming an active region within a semiconductor substrate. At least one insulating pattern may be formed on the active region, and a sacrificial pattern may be formed on the at least one insulating pattern. Silicon germanium patterns may be formed to adjoin sidewalls of the insulating and sacrificial patterns. A mold may be formed adjoining upper portions of the silicon germanium patterns by etching the sacrificial pattern. A molded pattern may be formed to partially fill the mold. The molded pattern may be formed of one of a conductive material and a stacked insulating material and conductive material. A protective pattern may be formed on the molded pattern to substantially fill the mold. The silicon germanium patterns may be removed from the semiconductor substrate. The silicon germanium patterns may be removed using a wet etchant having at least one of hydrogen chloride, ammonium hydroxide, and hydrogen peroxide.

According to some embodiments, forming the gate structure may include forming first to fourth insulating layers, forming a photoresist pattern on the fourth insulating layer, forming first to fourth insulating patterns by etching the first to fourth insulating layers using the photoresist pattern, removing the photoresist pattern, and forming spacers on sidewalls of the first to fourth insulating patterns. The first to fourth insulating layers may be formed on the active region. The first insulating layer may include silicon oxide. The second insulating layer may include silicon nitride. The third insulating layer may include silicon oxide and metal oxide that are stacked. The fourth insulating layer may include silicon oxide. The photoresist pattern may be formed on the fourth insulating layer. The photoresist pattern may be removed from the semiconductor substrate after forming the first to fourth insulating patterns. The spacers may include an insulating material having a different etch rate from the first to fourth insulating patterns.

According to some embodiments, forming the silicon germanium patterns may include forming a silicon germanium layer and etching the silicon germanium layer. The silicon germanium layer may be formed on the active region to cover the fourth insulating pattern and the spacers. The silicon germanium layer may be formed by chemical vapor deposition. The silicon germanium layer may be formed to have a different etch rate from the first to fourth insulating patterns and the spacers. The silicon germanium layer may be etched to expose the fourth insulating pattern.

According to some embodiments, forming the mold may include etching the fourth insulating pattern. The fourth insulating pattern may be etched using the silicon germanium patterns and the spacers as an etch buffer layer to expose the third insulating pattern. The fourth insulating pattern may be removed by a dry or wet etching technique.

According to some embodiments, forming the molded pattern may include forming a conductive layer and forming a conductive pattern. The conductive layer may be formed on the silicon germanium patterns to fill the mold. The conductive layer may include metal nitride and metal that are stacked. The metal nitride may be formed to conformally cover the mold. The conductive pattern may be formed in the mold by etching the conductive layer to expose the silicon germanium patterns and at least portions of sidewalls of the mold.

According to some embodiments, forming the gate structure may include forming first to fourth insulating layers, forming a photoresist pattern, forming a fourth insulating pattern, removing the photoresist pattern, forming spacers, and forming first to third insulating patterns. The first to fourth insulating layers may be formed on the active region. The first insulating layer may include silicon oxide. The second insulating layer may include silicon nitride. The third insulating layer may include silicon oxide and metal oxide that are stacked. The fourth insulating layer may include silicon oxide. The photoresist pattern may be formed on the fourth insulating layer. The fourth insulating pattern may be formed by etching the fourth insulating layer using the photoresist pattern as an etch mask to expose the third insulating layer. The photoresist pattern may be removed from the semiconductor substrate after the fourth insulating pattern is formed. The spacers may be formed on sidewalls of the fourth insulating pattern. The spacers may include an insulating material having a different etch rate from the first to third insulating layers and the fourth insulating pattern. The first to third insulating patterns may be formed by etching the first to third insulating layers using the fourth insulating pattern and the spacers as an etch mask.

According to some embodiments, forming the silicon germanium patterns may include forming a silicon germanium layer, and etching the silicon germanium layer. The silicon germanium layer may be formed on the active region to cover sidewalls of the first to fourth insulating patterns and the spacers. The silicon germanium layer may be formed by chemical vapor deposition. The silicon germanium layer may be formed to have a different etch rate from the first to fourth insulating patterns and the spacers. The silicon germanium layer may be etched to expose the fourth insulating pattern.

According to some embodiments, forming the mold may include etching the fourth insulating pattern. The fourth insulating pattern may be etched using the silicon germanium patterns and the spacers as an etch buffer layer to expose the third insulating pattern between the spacers. The fourth insulating pattern may be removed by a dry or wet etching technique.

According to some embodiments, forming the molded pattern may include forming a conductive layer, and forming a conductive pattern. The conductive layer may be formed on the silicon germanium pattern to fill the mold. The conductive layer may include metal nitride and metal that are stacked. The metal nitride may be formed to conformally cover the mold. The conductive pattern may be formed in the mold by etching the conductive layer to expose the silicon germanium patterns and at least portions of sidewalls of the mold.

According to some embodiments, forming the gate structure may include forming first to third insulating layers, forming a photoresist pattern, forming first to third insulating patterns, and removing the photoresist pattern. The first to third insulating layers may be formed on the active region. The first insulating layer may include silicon oxide. The second insulating layer may include silicon nitride. The third insulating layer may include silicon oxide. The photoresist pattern may be formed on the third insulating layer. The first to third insulating patterns may be formed by etching the first to third insulating layers using the photoresist pattern as an etch mask to expose the active region. The photoresist pattern may be removed from the semiconductor substrate after the first to third insulating patterns are formed.

According to some embodiments, forming the silicon germanium patterns may include forming and etching a silicon germanium layer. The silicon germanium layer may be formed on the active region to cover sidewalls of the first to third insulating patterns. The silicon germanium layer may be formed by chemical vapor deposition. The silicon germanium layer may be formed to have a different etch rate from the first to third insulating patterns. The silicon germanium layer may be etched to expose the third insulating pattern.

According to some embodiments, forming the mold may include etching the third insulating pattern. The third insulating pattern may be etched using the silicon germanium patterns as an etch buffer layer to expose the second insulating pattern. The third insulating pattern may be removed by a dry or wet etching technique.

According to some embodiments, forming the molded pattern may include forming a fourth insulating layer and a conductive layer, and forming a fourth insulating pattern and a conductive pattern. The fourth insulating layer and the conductive layer may be formed on the silicon germanium pattern to fill the mold. The fourth insulating layer may include silicon oxide and metal oxide that are stacked. The conductive layer may include metal nitride and metal that are stacked. The fourth insulating layer may be formed to conformally cover the mold along with the metal nitride. The fourth insulating pattern and the conductive pattern may be formed in the mold by etching the fourth insulating layer and the conductive layer to expose the silicon germanium patterns and at least portions of sidewalls of the mold.

According to some embodiments, forming the protective pattern may include forming a protective layer, and etching the protective layer. The protective layer may be formed on the molded pattern to fill the mold and cover the silicon germanium patterns. The protective layer may include an insulating material having a different etch rate from the silicon germanium patterns. The insulating material may include silicon oxide, silicon nitride and silicon oxynitride. The protective layer may be etched to expose the silicon germanium patterns.

According to some embodiments, removing the silicon germanium patterns may include etching the silicon germanium patterns with the wet etchant using the active region and the protective pattern as an etch buffer layer.

### BRIEF DESCRIPTION OF THE DRAWINGS

Various embodiments are described in further detail below with reference to the accompanying drawings. It should be understood that various aspects of the drawings may have been exaggerated for clarity.

FIG. 1 is a plan view of semiconductor devices according to some embodiments.

FIG. 2 is a cross-sectional view of a semiconductor device taken along line I-I′ of FIG. 1.

FIGS. 3 to 6 are cross-sectional views taken along line IT of FIG. 1, illustrating methods of fabricating semiconductor devices.

FIGS. 7 to 9 are cross-sectional views taken along line I-I′ of FIG. 1, illustrating methods of fabricating semiconductor devices.

FIGS. 10 to 12 are cross-sectional views taken along line I-I′ of FIG. 1, illustrating methods of fabricating semiconductor devices.

### DETAILED DESCRIPTION OF THE EMBODIMENTS

Various embodiments will now be described more fully with reference to the accompanying drawings in which some embodiments are shown. In the drawings, the thicknesses of layers and regions may be exaggerated for clarity.

Detailed illustrative embodiments are disclosed herein. However, specific structural and functional details disclosed herein are merely representative for purposes of describing various embodiments. This invention, however, may be embodied in many alternate forms and should not be construed as limited to only embodiments set forth herein.

Accordingly, while various embodiments are capable of various modifications and alternative forms, embodiments thereof are shown by way of example in the drawings and will herein be described in detail. It should be understood, however, that there is no intent to limit various embodiments to the particular forms disclosed, but on the contrary, various embodiments are to cover all modifications, equivalents, and alternatives falling within the scope of the invention. Like numbers refer to like elements throughout the description of the figures.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, or section from another. For example, a first element could be termed a second element, and, similarly, a second element could be termed a first element, without departing from the teachings of the present invention. As used herein, the term “and/or” includes any and all combinations of one or more of the associated listed items.

It will be understood that when an element, component, region, layer, or section is referred to as being “connected” or “coupled” to another element, component, region, layer, or section, it can be directly connected or coupled to the other element, component, region, layer, or section or intervening elements, components, regions, layers, or sections may be present. In contrast, when an element, component, region, layer, or section is referred to as being “directly connected” or “directly coupled” to another element, component, region, layer, or section, there are no intervening elements, components, regions, layers, or sections present. Other words used to describe the relationship between elements, components, regions, layers, or sections should be interpreted in a like fashion (e.g., “between” versus “directly between,” “adjacent” versus “directly adjacent,” etc.).

The terminology used herein is for the purpose of describing particular embodiments only and is not intended to be limiting of various embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Various embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, various embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implantation concentration) at its edges rather than an abrupt change from an implanted region to a non-implanted region. Likewise, a silicon germanium region formed by implantation may result in some implantation in the region between the silicon germanium region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe various embodiments, various aspects will be described in detail with reference to the attached drawings. However, the present invention is not limited to embodiments described.

Hereinafter, gate structures of semiconductor devices and methods of forming gate structures of semiconductor devices will be described with reference to the figures in further detail.

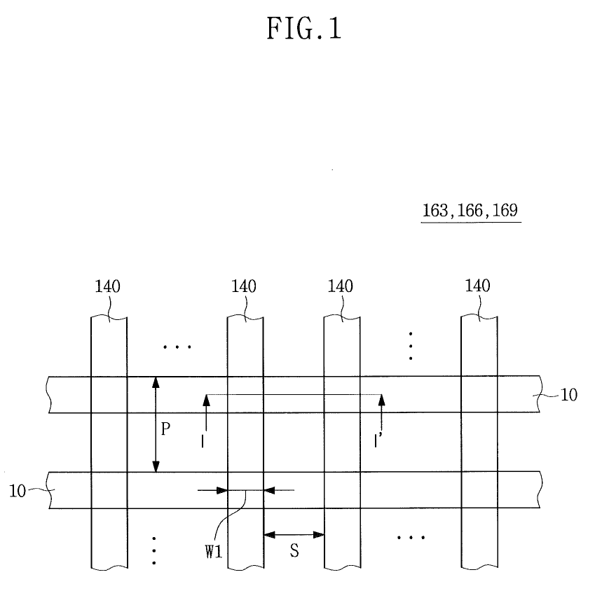

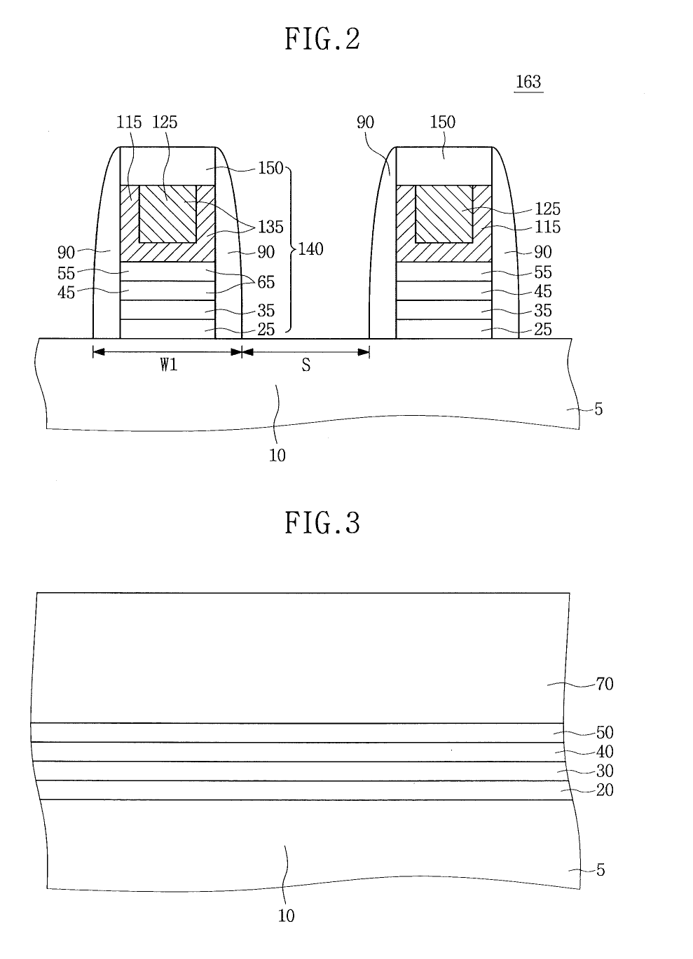

FIG. 1 is a plan view of a semiconductor device according to some embodiments, where the semiconductor device may be one of the semiconductor devices 163, 166, or 169, illustrated in FIG. 2-6, 7-9, or 10-12, respectively.

Referring to FIG. 1, each semiconductor device 163, 166, or 169 according to various embodiments may have a cell array region and a peripheral circuit region. The cell array region may include a plurality of active regions 10. The active regions 10 may have the same pitch P and be aligned parallel to each other. The cell array region may include gate structures 140. The gate structures 140 may cross the active regions 10. The gate structures 140 may have the same pitch W1+S and be aligned parallel to each other.

The peripheral circuit region may be disposed around the cell array region. The peripheral circuit region may include active regions, which may be the same as or different from, in form, those of the cell array region. In addition, the peripheral circuit region may have gate structures, which may be the same as or different from, in form, those of the cell array region.

Referring to FIG. 2, the semiconductor device 163 according to various embodiments may include gate structures 140 disposed on a semiconductor substrate 5. The semiconductor substrate 5 may have an isolation layer. FIG. 2 is a cross-sectional view, taken along line I-I′ of FIG. 1, of a semiconductor device, and the isolation layer may define the active region 10 of FIG. 1. The gate structures 140 may be disposed on the active region 10 and the isolation layer. Each gate structure 140 may include a tunneling insulating pattern 25, a data storage pattern 35, a blocking insulating pattern 65, and a conductive pattern 135 that are stacked on the semiconductor substrate 5.

The tunneling insulating pattern 25 may be disposed on the active region 10. The tunneling insulating pattern 25 may be in contact with the active region 10. Alternatively, the tunneling insulating pattern 25 may be disposed on the active region 10 and the isolation layer. The tunneling insulating pattern 25 may be in contact with the active region 10 and the isolation layer. The tunneling insulating pattern 25 may serve as an electrical tunneling barrier against charges traveling toward the data storage pattern 35 from the semiconductor substrate 5.

The data storage pattern 35 may be disposed on the tunneling insulating pattern 25 to cross the active region 10 and the isolation layer. The data storage pattern 35 may be in contact with the tunneling insulating pattern 25. The data storage pattern 35 may include an insulating material. The data storage pattern 35 may provide trap sites of charges. The data storage pattern 35 may set the non-volatile memory cell to a program state or an erase state by receiving an influence of an electric field generated by the conductive pattern 135.

The blocking insulating pattern 65 may be disposed on the data storage pattern 35. The blocking insulating pattern 65 may be in contact with the data storage pattern 35. The blocking insulating pattern 65 may physically and electrically prevent the travel of charges between the conductive pattern 135 and the data storage pattern 35. The blocking insulating pattern 65 may include first and second insulating patterns 45 and 55 that are stacked. The first and second insulating patterns 45 and 55 may have different dielectric constants from each other.

The conductive pattern 135 may be disposed on the blocking insulating pattern 65. The conductive pattern 135 may be in contact with the blocking insulating pattern 65. The conductive pattern 135 may include first and second conductive patterns 115 and 125 that are stacked. The first conductive pattern 115 may be formed in a concave shape, and surround the second conductive pattern 125. The first conductive pattern 115 may surround a bottom surface and sidewalls of the second conductive pattern 125, and expose a top surface of the second conductive pattern 125. The conductive pattern 135 may serve as a control gate of the non-volatile memory cell.

Each gate structure 140 may further include spacers 90 and a protective pattern 150. The protective pattern 150 may be disposed on the conductive pattern 135. The protective pattern 150 may be in contact with the conductive pattern 135. The protective pattern 150 may include an insulating material. Sidewalls of the protective pattern 150 may have substantially the same surface alignment as sidewalls of the tunneling insulating pattern 25, the data storage pattern 35, the blocking insulating pattern 65, and the conductive pattern 135.

The protective pattern 150 may have the same width as the tunneling insulating pattern 25, the data storage pattern 35, the blocking insulating pattern 65, and the conductive pattern 135. The spacers 90 may be disposed on the sidewalls of the tunneling insulating pattern 25, the data storage pattern 35, the blocking insulating pattern 65, the conductive pattern 135, and the protective pattern 150. The spacers 90 may be disposed on the active region 10 and the isolation layer. The spacers 90 may be in contact with the sidewalls of the tunneling insulating pattern 25, the data storage pattern 35, the blocking insulating pattern 65, the conductive pattern 135, and the protective pattern 150.

The spacers 90 may include an insulating material. The gate structures 140 may be disposed on the semiconductor substrate 5 to have a predetermined size of pitch W1+S.

Methods of forming gate structures of semiconductor devices according to various embodiments are described with reference to FIGS. 3 to 12.

FIGS. 3 to 6 are cross-sectional views taken along line I-I′ of FIG. 1, illustrating methods of fabricating semiconductor devices 163.

Referring to FIG. 3, a semiconductor substrate 5 may be prepared according to various embodiments. The semiconductor substrate 5 may include an isolation layer. The isolation layer may be formed to define at least one active region 10 of FIG. 1. A tunneling insulating layer 20 may be formed on the active region 10. Alternatively, the tunneling insulating layer 20 may be formed on the active region 10 and the isolation layer. The tunneling insulating layer 20 may include an isolating material, for example, silicon oxide. A data storage layer 30 may be formed on the tunneling insulating layer 20.

The data storage layer 30 may be formed on the isolation layer and the active region 10. The data storage layer 30 may include an insulating material, for example, silicon nitride. A first insulating layer 40 and a second insulating layer 50 may be formed on the data storage layer 30. The first and second insulating layers 40 and 50 may be formed to have different dielectric constants from each other. The first insulating layer 40 may include an insulating material such as silicon oxide, for example. The second insulating layer 50 may include an insulating material such as metal oxide, for example. A sacrificial layer 70 may be formed on the second insulating layer 50. The sacrificial layer 70 may include an insulating material such as silicon oxide, for example.

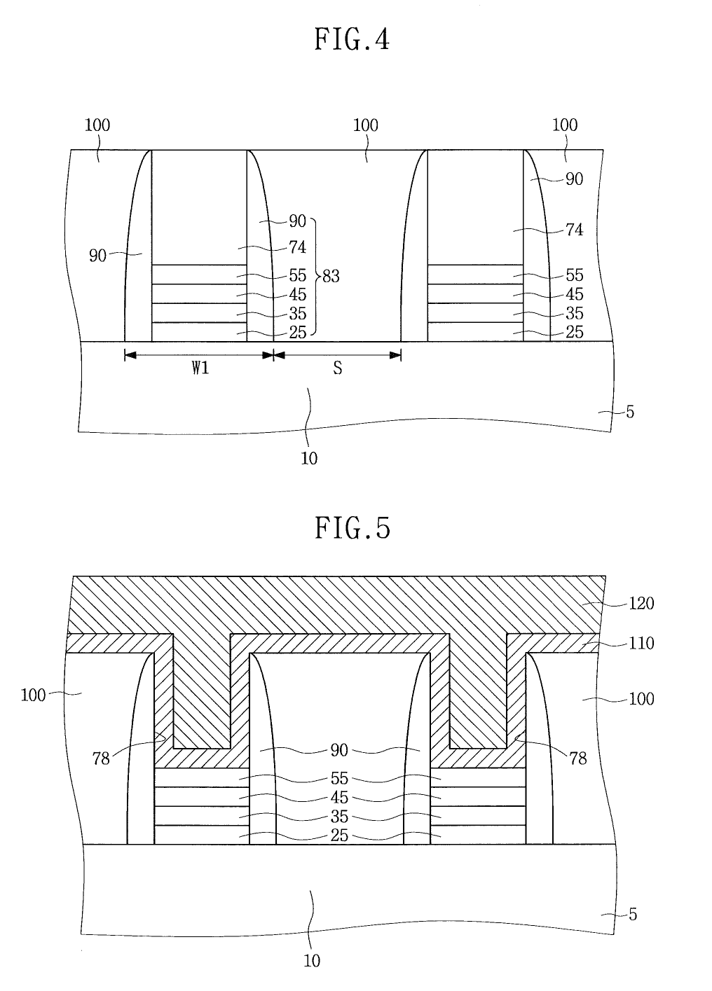

Referring to FIG. 4, photoresist patterns may be formed on the sacrificial layer 70 of FIG. 3. The tunneling insulating layer 20, the data storage layer 30, the first insulating layer 40, the second insulating layer 50, and the sacrificial layer 70 of FIG. 3 may be etched using the photoresist patterns as etch masks, thereby forming tunneling insulating patterns 25, data storage patterns 35, first insulating patterns 45, second insulating patterns 55, and sacrificial patterns 74. The first and second insulating patterns 45 and 55 may constitute a blocking insulating pattern, such as the blocking insulating pattern 65 of FIG. 2. After the tunneling insulating patterns 25, the data storage patterns 35, the first insulating patterns 45, the second insulating patterns 55, and the sacrificial patterns 74 are formed, the photoresist patterns may be removed from the semiconductor substrate 5.

Spacers 90 may be formed on sidewalls of the tunneling insulating patterns 25, the data storage patterns 35, the first insulating patterns 45, the second insulating patterns 55, and the sacrificial patterns 74. The spacers 90 may include an insulating material having a different etch rate from the tunneling insulating patterns 25, the data storage patterns 35, the first insulating patterns 45, the second insulating patterns 55, and the sacrificial patterns 74. Alternatively, the spacers 90 may include an insulating material having the same etch rate as the data storage patterns 35.

The spacers 90 may constitute a pre-mold pattern 83 along with the tunneling insulating patterns 25, the data storage patterns 35, the first insulating patterns 45, the second insulating patterns 55, and the sacrificial patterns 74. The pre-mold pattern 83 may be disposed on the active region 10 and the isolation layer to cross the active region 10. The pre-mold pattern 83 may be formed to have a predetermined size of pitch W1+S.

A silicon germanium layer may be formed on the isolation layer and the active region 10 to adjoin sidewalls of the pre-mold pattern 83. The silicon germanium layer may be formed to have a different etch rate from the tunneling insulating patterns 25, the data storage patterns 35, the first insulating patterns 45, the second insulating patterns 55, and the sacrificial patterns 74. The silicon germanium layer may include silicon germanium (SiGe) using chemical vapor deposition (CVD). Silicon germanium patterns 100 may be formed by etching the silicon germanium layer to expose the sacrificial patterns 74.

The silicon germanium patterns 100 may adjoin sidewalls of the pre-mold pattern 83.

Referring to FIG. 5, the sacrificial patterns 74 of FIG. 4 may be etched using the spacers 90 and the silicon germanium patterns 100 as an etch buffer layer to expose the second insulating patterns 55. The sacrificial patterns 74 may be removed from the pre-mold pattern 83 using dry or wet etching technology. Thus, the pre-mold pattern 83 may be partially etched at upper portions thereof, thereby forming a mold 78. The mold 78 may include the spacers 90 and may adjoin upper portions of the silicon germanium patterns 100.

A conductive layer may be formed on the silicon germanium patterns 100 to fill the mold 78. The conductive layer may be formed of a first conductive layer 110 and a second conductive layer 120 that are stacked. The first conductive layer 110 may be formed to conformally cover the mold 78. The first conductive layer 110 may include metal nitride. The metal nitride may include tantalum nitride (TaN), titanium nitride (TiN), or tungsten nitride (WN).

The second conductive layer 120 may be formed to substantially fill the mold 78. The second conductive layer 120 may include metal. The metal may include tantalum (Ta), titanium (Ti), or tungsten (W).

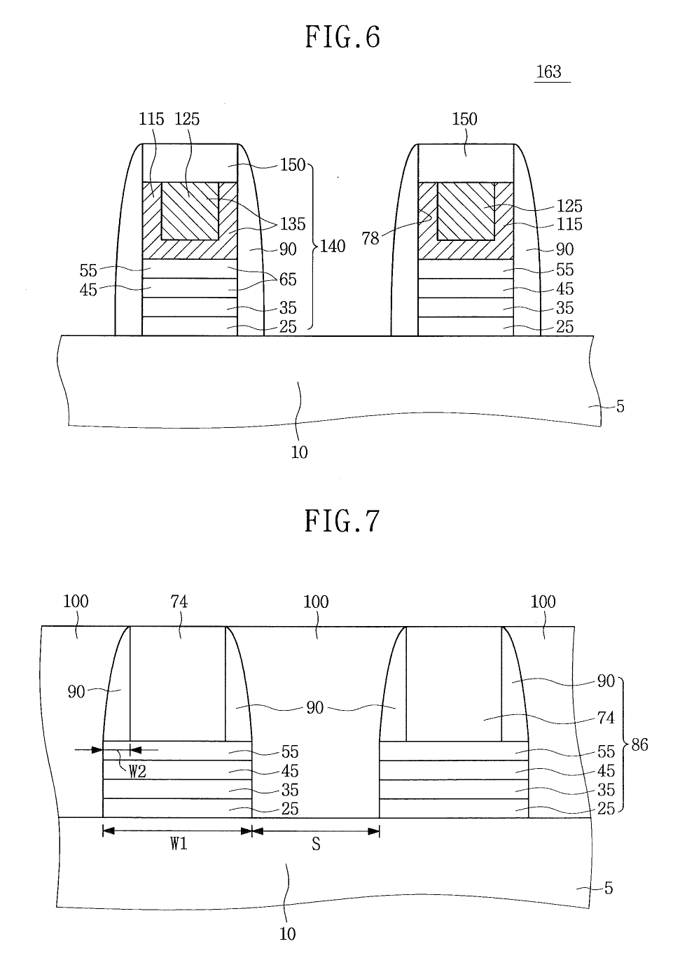

Referring to FIG. 6, the conductive layer may be etched to expose the silicon germanium patterns 100 of FIG. 5 and at least portions of sidewalls of the mold 78 according to various embodiments, thereby forming first and second conductive patterns 115 and 125 in the mold 78. The first conductive patterns 115 may be formed to conformally cover the mold 78 along bottom surfaces and sidewalls of the mold 78. The second conductive patterns 125 may be surrounded by the first conductive patterns 115. The first and second conductive patterns 115 and 125 may constitute molded patterns 135.

During the formation of the molded patterns 135, the first and second conductive patterns 115 and 125 are molded by the second insulating patterns 55 and the spacers 90, so that the tunneling insulating patterns 25 and the data storage patterns 35 cannot be contaminated. A protective layer may be formed on the molded patterns 135 to fill the mold 78 and cover the silicon germanium patterns 100. The protective layer may be formed to have a different etch rate from the silicon germanium patterns 100. The protective layer may include an insulating material, for example, silicon oxide, silicon nitride, or silicon oxynitride.

The protective layer may be etched to expose the silicon germanium patterns 100, thereby forming protective patterns 150. The protective patterns 150 may be formed to substantially fill the mold 78. The silicon germanium patterns 100 may be etched with a wet etchant using the active region 10, the isolation layer, the spacers 90, and the protective patterns 150 as an etch buffer layer. The wet etchant may include at least one of hydrogen chloride (HCl), ammonium hydroxide (NH₄OH), and hydrogen peroxide (H₂O₂).

The wet etchant may remove the silicon germanium patterns 100 from the semiconductor substrate 5. Thus, the protective patterns 150 may constitute gate structures 140 along with the tunneling insulating patterns 25, the data storage patterns 35, the first insulating patterns 45, the second insulating patterns 55, the spacers 90, and the molded patterns 135. The gate structures 140 may correspond to non-volatile memory cells. The gate structures 140 may constitute a semiconductor device 163 along with the semiconductor substrate 5 according to various embodiments.

FIGS. 7 to 9 are cross-sectional views taken along line IT of FIG. 1, illustrating methods of fabricating semiconductor devices 166. FIGS. 7 to 9 use like reference numerals to denote like elements with FIGS. 3 to 6.

A tunneling insulating layer 20, a data storage layer 30, a first insulating layer 40, a second insulating layer 50, and a sacrificial layer 70 may be formed on a semiconductor substrate 5 as shown in FIG. 3 according to various embodiments. Photoresist patterns may be formed on the sacrificial layer 70. The photoresist patterns may have different shapes from the photoresist patterns of FIG. 4. Referring to FIG. 7, sacrificial patterns 74 may be formed by etching the sacrificial layer 70 using the photoresist patterns as an etch mask to expose the second insulating layer 50.

After the formation of the sacrificial patterns 74, the photoresist patterns may be removed from the semiconductor substrate 5. Spacers 90 may be formed on sidewalls of the sacrificial patterns 74. The tunneling insulating layer 20, the data storage layer 30, the first insulating layer 40, and the second insulating layer 50 may be etched using the sacrificial patterns 74 and the spacers 90 as an etch mask, thereby forming tunneling insulating patterns 25, data storage patterns 35, first insulating patterns 45, and second insulating patterns 55.

The tunneling insulating patterns 25, the data storage patterns 35, the first insulating patterns 45, and the second insulating patterns 55 may extend from sidewalls of the sacrificial patterns 74 to sidewalls of the spacers 90 in both directions by a predetermined width W2. Thus, lower portions of the sidewalls of the spacer 90 may be aligned with the sidewalls of the tunneling insulating patterns 25, the data storage patterns 35, the first insulating patterns 45, and the second insulating patterns 55. The spacers 90 may constitute a pre-mold pattern 86 along with the tunneling insulating patterns 25, the data storage patterns 35, the first insulating patterns 45, the second insulating patterns 55, and the sacrificial patterns 74.

The pre-mold pattern 86 may have the same pitch W1+S as the pre-mold pattern 83 of FIG. 4. A silicon germanium layer may be formed on an isolation layer and an active region 10 to adjoin sidewalls of the pre-mold pattern 86. Silicon germanium patterns 100 may be formed by etching the silicon germanium layer to expose the sacrificial patterns 74. The silicon germanium patterns 100 may be formed around the pre-mold pattern 86.

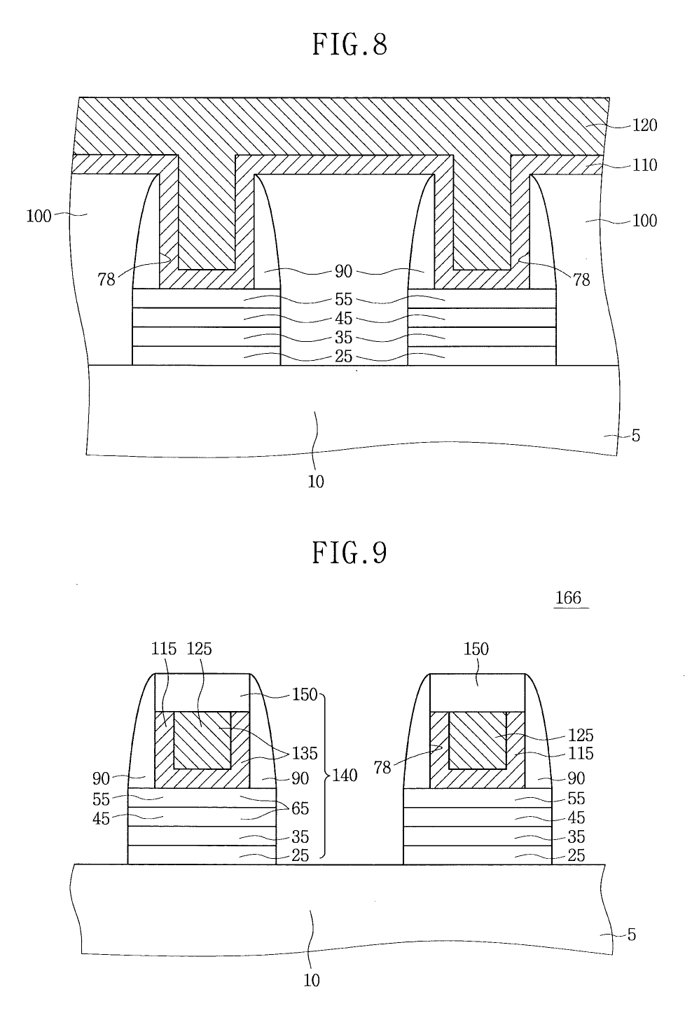

Referring to FIG. 8, according to various embodiments, mold 78 may be formed by etching the sacrificial patterns 74 of FIG. 7 using the spacers 90 and the silicon germanium patterns 100 as an etch buffer to expose the second insulating patterns 55 between the spacers 90. The mold 78 may adjoin upper portions of the silicon germanium patterns 100. A conductive layer may be formed on the silicon germanium patterns 100 to fill the mold 78.

The conductive layer may be formed of a first conductive layer 110 and a second conductive layer 120 that are stacked. The first conductive layer 110 may be formed to conformally cover the mold 78. The second conductive layer 120 may be formed to substantially fill the mold 78.

Referring to FIG. 9, first and second conductive patterns 115 and 125 may be formed in the mold 78 by etching the conductive layer to expose the silicon germanium patterns 100 of FIG. 8 and at least portions of the sidewalls of the mold 78. The first conductive patterns 115 may be formed to conformally cover the mold 78 along bottom surfaces and sidewalls of the mold 78. The second conductive patterns 125 may be surrounded by the first conductive patterns 115. The first and second conductive patterns 115 and 125 may constitute molded patterns 135.

During the formation of the molded patterns 135, the first and second conductive patterns 115 and 125 may be molded by the second insulating patterns 55 and the spacers 90, so that the tunneling insulating patterns 25 and the data storage patterns 35 cannot be contaminated. A protective layer may be formed on the molded patterns 135 to fill the mold 78 and cover the silicon germanium patterns 100. Protective patterns 150 may be formed by etching the protective layer to expose the silicon germanium patterns 100. The protective patterns 150 may be formed to substantially fill the mold 78.

The silicon germanium patterns 100 may be etched with a wet etchant using the active region 10, the isolation layer, the spacers 90, and the protective patterns 150 as an etch buffer layer. The wet etchant may include the same material as the wet etchant of FIG. 6. The wet etchant may remove the silicon germanium patterns 100 from the semiconductor substrate 5. Thus, the protective patterns 150 may constitute gate structures 140 along with the tunneling insulating patterns 25, the data storage patterns 35, the first insulating patterns 45, the second insulating patterns 55, the spacers 90, and the molded patterns 135.

In the gate structures 140, the sidewalls of the tunneling insulating patterns 25, the data storage patterns 35, the first insulating patterns 45, and the second insulating patterns 55 may have the same surface alignment. However, in the gate structures 140, sidewalls of the molded patterns 135 and the protective patterns 150 may have different surface alignments from the sidewalls of the tunneling insulating patterns 25, the data storage patterns 35, the first insulating patterns 45, and the second insulating patterns 55. Here, the first and second insulating patterns 45 and 55 may constitute blocking insulating patterns 65.

The blocking insulating patterns 65 may further alleviate the influence of an electric field generated by the molded patterns 135 around the spacers 90 compared to FIG. 6. This is because the blocking insulating patterns 65 may extend beyond the sidewalls of the molded patterns 135. The gate structures 140 may constitute a semiconductor device 166 along with the semiconductor substrate 5 according to various embodiments.

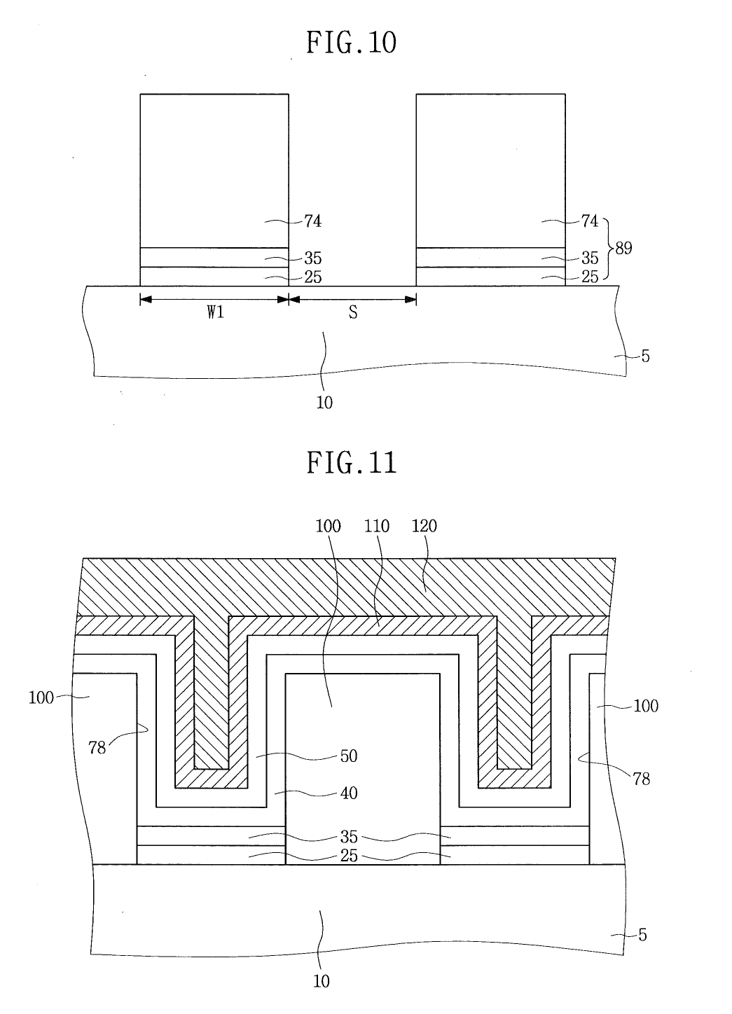

FIGS. 10 to 12 are cross-sectional views taken along line I-I′ of FIG. 1, illustrating methods of fabricating semiconductor devices 169. FIGS. 10 to 12 use like reference numerals to denote like elements with FIGS. 7 to 9.

A tunneling insulating layer 20, a data storage layer 30 and a sacrificial layer 70 may be formed on a semiconductor substrate 5 according to various embodiments. Photoresist patterns may be formed on the sacrificial layer 70. The tunneling insulating layer 20, the data storage layer 30, and the sacrificial layer 70 may be etched using the photoresist patterns as an etch mask, thereby forming tunneling insulating patterns 25, data storage patterns 35, and sacrificial patterns 74, as shown in FIG. 10. The tunneling insulating patterns 25, the data storage patterns 35, and the sacrificial patterns 74 may constitute a pre-mold pattern 89.

After the pre-mold pattern 89 is formed, the photoresist patterns may be removed from the semiconductor substrate 5.

Referring to FIG. 11, a silicon germanium layer may be formed on an isolation layer and an active region 10 to adjoin sidewalls of the pre-mold pattern 89 of FIG. 10 according to various embodiments. Silicon germanium patterns 100 may be formed by etching the silicon germanium layer to expose the sacrificial patterns 74 of FIG. 10. The silicon germanium patterns 100 may be formed around the pre-mold pattern 89. Mold 78 may be formed by etching the sacrificial patterns 74 using the silicon germanium patterns 100 as an etch buffer layer to expose the data storage patterns 35.

A first insulating layer 40, a second insulating layer 50 and a conductive layer may be formed on the silicon germanium patterns 100 to fill the mold 78. The conductive layer may be formed of a first conductive layer 110 and a second conductive layer 120 that are stacked. The first conductive layer 110 may be formed to conformally cover the mold 78 along with the first and second insulating layers 40 and 50. The second conductive layer 120 may be formed to substantially fill the mold 78.

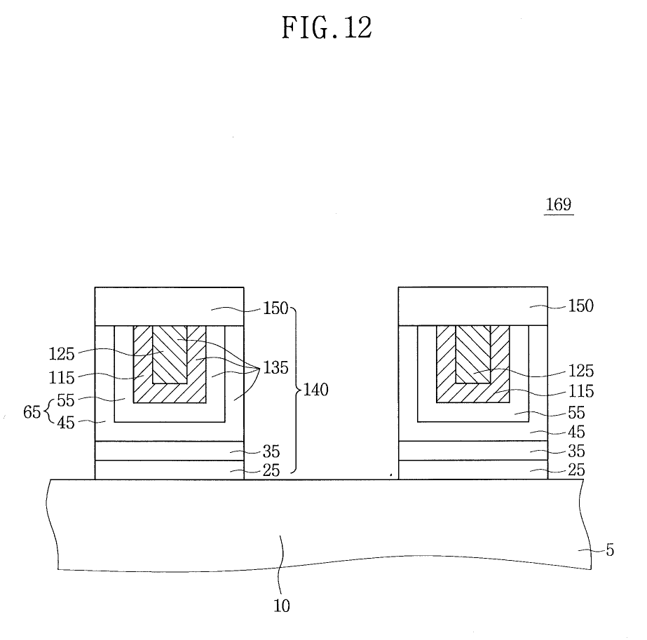

Referring to FIG. 12, the first insulating layer 40, the second insulating layer 50, the first conductive layer 110, and the second conductive layer 120 of FIG. 11 may be etched, thereby forming first insulating patterns 45, second insulating patterns 55, first conductive patterns 115, and second conductive patterns 125. The first insulating patterns 45, the second insulating patterns 55, the first conductive patterns 115, and the second conductive patterns 125 may be formed in the mold 78 of FIG. 11 using the silicon germanium patterns 100 of FIG. 11 as an etch mask. The first insulating patterns 45, the second insulating patterns 55, the first conductive patterns 115, and the second conductive patterns 125 may be formed to expose the silicon germanium patterns 100 and at least portions of sidewalls of the mold 78.

The first insulating patterns 45, the second insulating patterns 55, and the first conductive patterns 115 may be stacked between the second conductive patterns 125 and the data storage patterns 35. The first insulating patterns 45, the second insulating patterns 55, and the first conductive patterns 115 may be stacked between the second conductive patterns 125 and the silicon germanium patterns 100. The first insulating patterns 45, the second insulating patterns 55, the first conductive patterns 115, and the second conductive patterns 125 may constitute molded patterns 135.

During the formation of the molded patterns 135, the first and second conductive patterns 115 and 125 may be molded by the first insulating patterns 45, the second insulating patterns 55, and the silicon germanium patterns 100, so that the tunneling insulating patterns 25 and the data storage patterns 35 cannot be contaminated. A protective layer may be formed on the molded patterns 135 to fill the mold 78 and cover the silicon germanium patterns 100. Protective patterns 150 may be formed by etching the protective layer to expose the silicon germanium patterns 100. The protective patterns 150 may be formed to substantially fill the mold 78.

The silicon germanium patterns 100 may be etched with a wet etchant using the active region 10, the isolation layer, the tunneling insulating patterns 25, the data storage patterns 35, the first insulating patterns 45, and the protective patterns 150 as an etch buffer layer. The wet etchant may include the same material as the wet etchant of FIG. 6. The wet etchant may remove the silicon germanium patterns 100 from the semiconductor substrate 5. Thus, the protective patterns 150 may constitute gate structures 140 along with the tunneling insulating patterns 25, the data storage patterns 35, and the molded patterns 135.

The first insulating patterns 45 and the second insulating patterns 55 may constitute blocking insulating patterns 65. The blocking insulating patterns 65 may further alleviate an influence of an electric field generated by the first and second conductive patterns 115 and 125 on the tunneling insulating patterns 25 and the data storage patterns 35. This is because the blocking insulating patterns 65 may surround the first and second conductive patterns 115 and 125. The gate structures 140 may constitute a semiconductor device 169 along with the semiconductor substrate 5 according to various embodiments.

As described above, various embodiments can provide a gate structure of a semiconductor device which ensures a desired patterning profile using molded patterns and prevents metal contamination through the molded pattern, and methods of fabricating the same. In addition, the various embodiments can benefit highly-integrated semiconductor devices by alleviating an electrical influence generated by a molded pattern on a layer under the molded pattern.

The foregoing is illustrative of various embodiments and is not to be construed as limiting thereof. Although various embodiments have been described, those skilled in the art will readily appreciate that many modifications are possible in various embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

1. A gate structure, comprising:
a first insulating pattern disposed on an active region of a semiconductor substrate;
a data storage pattern disposed on the first insulating pattern;
a second insulating pattern disposed on the data storage pattern;
a first conductive pattern conforming to the second insulating pattern and to sidewalls of a mold comprising the second insulating pattern; and
a second conductive pattern disposed within a cavity defined by the first conductive pattern.

2. The gate structure according to claim 1, wherein the first conductive pattern surrounds a bottom surface and sidewalls of the second conductive pattern and exposes a top surface of the second conductive pattern, and a protective pattern is disposed on the top surface of the second conductive pattern.

3. The gate structure according to claim 2, wherein the second insulating pattern includes lower and upper insulating patterns that are stacked and have different dielectric constants from each other.

4. The gate structure according to claim 3, wherein sidewalls of the first conductive pattern have substantially the same surface alignment as sidewalls of the first insulating pattern, the data storage pattern, the second insulating pattern, and the protective pattern.

5. The gate structure according to claim 4, wherein the mold comprises sidewall spacers disposed on sidewalls of the first insulating pattern, the data storage pattern, the second insulating pattern, the first conductive pattern, and the protective pattern.

6. The gate structure according to claim 3, wherein sidewalls of the first insulating pattern have substantially the same surface alignment as sidewalls of the data storage pattern and the second insulating pattern, and sidewalls of the first conductive pattern and the protective pattern have different surface alignments from sidewalls of the first insulating pattern, the data storage pattern, and the second insulating pattern.

7. The gate structure according to claim 6, wherein the mold comprises sidewall spacers disposed on sidewalls of the first conductive pattern and the protective pattern, and the sidewalls of the first insulating pattern, the data storage pattern, and the second insulating pattern are aligned with sidewalls of lower portions of the spacers.

8. The gate structure according to claim 3, wherein sidewalls and a bottom surface of the first conductive pattern are surrounded by the second insulating pattern, and the protective pattern is in contact with the first conductive pattern, the second conductive pattern, and the second insulating pattern.

9. The gate structure according to claim 8, wherein the first conductive pattern and the second conductive pattern comprise a control gate of a non-volatile memory cell, and the data storage pattern sets the non-volatile memory cell to a program state or an erase state by receiving an influence of an electric field generated by the first conductive pattern and the second conductive pattern.

10. The gate structure according to claim 9, wherein the protective pattern has a same width as the first insulating pattern and the data storage pattern, and has a different width from the first conductive pattern.

11-26. (canceled)
